(19) United States
(12) Patent Application Publication
(10) Pub. No.: US 2023/0282534 A1
(43) Pub. Date: Sep. 7, 2023

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventor: Takumi Shigemoto, Tokyo (JP)

(73) Assignee: Mitsubishi Electric Corporation, Tokyo (JP)

(21) Appl. No.: 18/053,161

(22) Filed: Nov. 7, 2022

(30) Foreign Application Priority Data
Mar. 2, 2022 (JP) 2022-031569

(51) Int. Cl. H01L 23/31; H01L 23/538; H01L 25/065; H01L 21/56

(52) U.S. Cl. CPC H01L 23/3121; H01L 23/5386; H01L 25/0655; H01L 21/56; H01L 2224/32225; H01L 24/32

(57) ABSTRACT

Provided is a semiconductor device including a metal circuit pattern. The metal circuit pattern includes a groove in which air bubbles hardly remain in a process of sealing a semiconductor element, and thereby hardly peels off from a sealant. The semiconductor device includes: an insulator; the metal circuit pattern disposed on the insulator; at least one semiconductor element bonded to an upper surface of the metal circuit pattern via a bonding material; and the sealant sealing the at least one semiconductor element, wherein the upper surface of the metal circuit pattern includes the groove in a region sealed by the sealant, the region being different from a region to which the at least one semiconductor element is bonded via the bonding material, and an angle between each side surface of the groove and an undersurface of the groove is an obtuse angle.

### BACKGROUND OF THE INVENTION

### Field of the Invention

The present disclosure relates to a semiconductor device and a method for manufacturing the semiconductor device.

### Description of the Background Art

For example, Japanese Patent Application Laid-Open No. 2021-145081 discloses a semiconductor device including a conductor to which a semiconductor chip is bonded via solder. The conductor has, in a surface on which the semiconductor chip is bonded, a first region wider than a region to which the semiconductor chip is connected. The conductor includes a recessed portion surrounding the periphery of the first region.

Semiconductor devices each including a metal circuit pattern to which semiconductor elements are bonded and which includes grooves have a problem that the metal circuit pattern easily peels off from a sealant, from a portion of the grooves in which air bubbles remain. This is caused by the air bubbles remaining in the grooves in a process of sealing the semiconductor elements.

### SUMMARY

The object of the present disclosure is to provide a semiconductor device including a metal circuit pattern. The metal circuit pattern includes a groove in which air bubbles hardly remain in a process of sealing a semiconductor element, and thereby hardly peels off from a sealant.

The semiconductor device according to the present disclosure includes: an insulator; a metal circuit pattern disposed on the insulator; at least one semiconductor element bonded to an upper surface of the metal circuit pattern via a bonding material; and a sealant sealing the at least one semiconductor element. The upper surface of the metal circuit pattern includes a groove in a region sealed by the sealant, the region being different from a region to which the at least one semiconductor element is bonded via the bonding material. An angle between each side surface of the groove and an undersurface of the groove is an obtuse angle.

The present disclosure thereby provides the semiconductor device including the metal circuit pattern. The metal circuit pattern includes the groove in which air bubbles hardly remain in a process of sealing a semiconductor element, and thereby hardly peels off from the sealant.

### BRIEF DESCRIPTION OF THE DRAWINGS

FIG. 1 is a plan view of a semiconductor device according to Embodiment 1;

FIG. 2 is a cross-sectional view of the semiconductor device according to Embodiment 1 which is taken along a line A-A in FIG. 1;

FIG. 3 illustrates an enlarged partial cross-sectional view of a region X in FIG. 2;

FIG. 4 illustrates an example semiconductor device according to Embodiment 2;

FIG. 5 illustrates another example of the semiconductor device according to Embodiment 2;

FIG. 6 illustrates an example semiconductor device according to Embodiment 3;

FIG. 7 illustrates another example of the semiconductor device according to Embodiment 3;

FIG. 8 illustrates an example semiconductor device according to Embodiment 4; and

FIG. 9 is a cross-sectional view of the semiconductor device according to Embodiment 4 which is taken along a line B-B in FIG. 8.

### DESCRIPTION OF THE PREFERRED EMBODIMENTS

Although the description below sometimes uses the terms representing particular directions including “above” and “below”, these terms are used for convenience to facilitate the understanding of the details of Embodiments, and do not limit directions in, for example, manufacturing or using a semiconductor device.

### A. Embodiment 1

### [A-1. Structure]

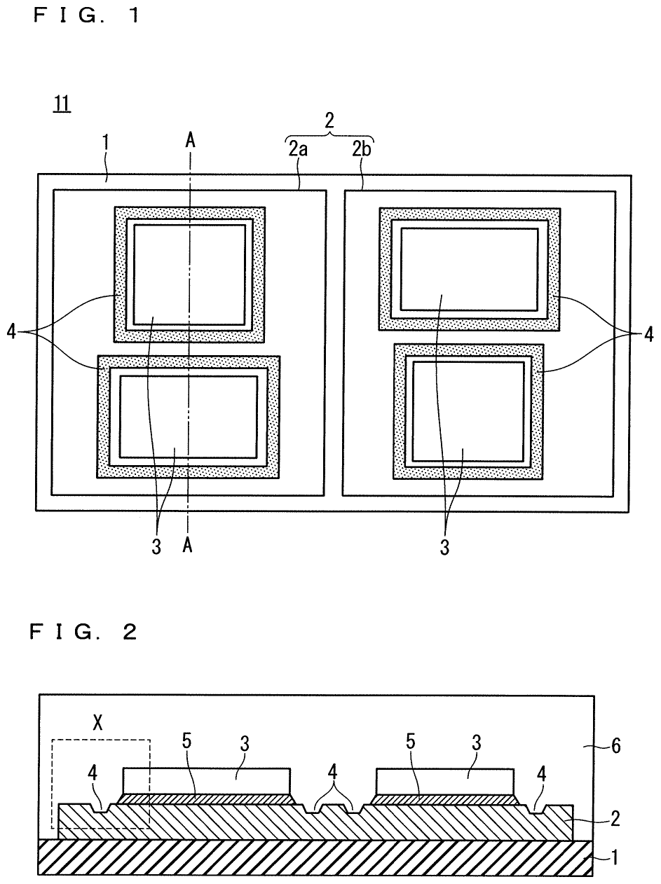

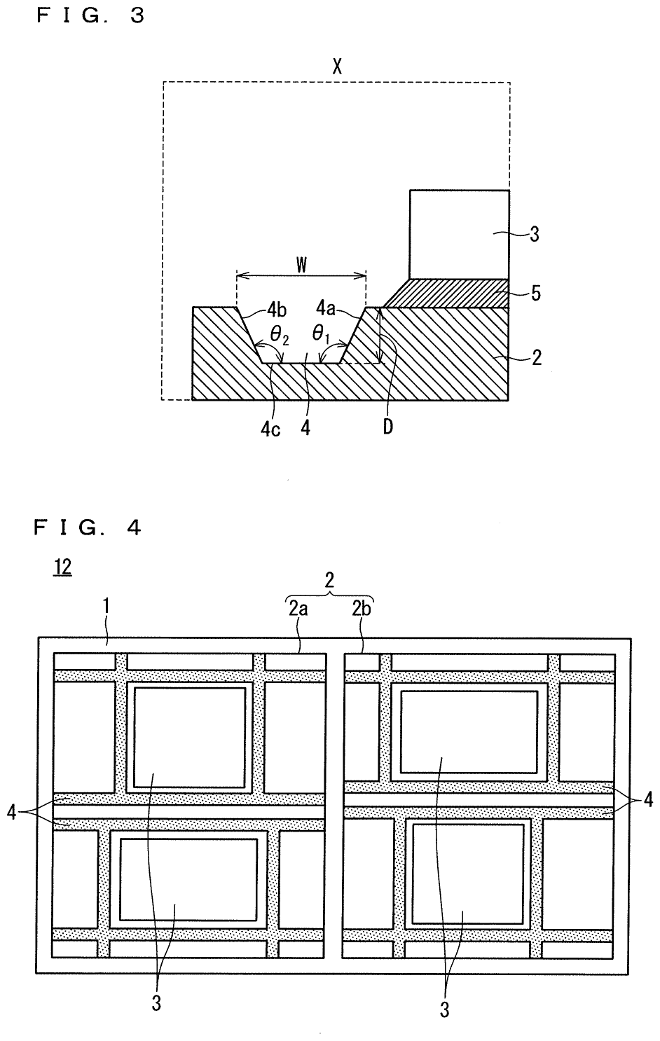

FIG. 1 is a partial plan view illustrating a part of a structure of a semiconductor device 11 according to Embodiment 1. FIG. 2 is a cross-sectional view of the semiconductor device 11 which is taken along a line A-A in FIG. 1. FIG. 3 illustrates an enlarged partial cross-sectional view of a region X enclosed by broken lines in FIG. 2.

The semiconductor device 11 includes an insulator 1, a metal circuit pattern 2, semiconductor elements 3, a bonding material 5, and a sealant 6. The illustration of the sealant 6 is omitted in FIGS. 1 and 3. Although the semiconductor device 11 further includes, for example, wires or leads as constituent elements of the circuit, the illustration of such elements is omitted in FIGS. 1 to 3.

The metal circuit pattern 2 is disposed on the insulator 1. The semiconductor elements 3 are bonded to the upper surface of the metal circuit pattern 2 via the bonding material 5.

Although FIG. 1 illustrates that the metal circuit pattern 2 includes two pattern regions, that is, pattern regions 2a and 2b, the metal circuit pattern 2 may be a single pattern region as a whole, or separated into at least three pattern regions.

Grooves 4 are formed on the upper surface of the metal circuit pattern 2. The grooves 4 are formed in regions sealed by the sealant 6 which are different from regions to which the semiconductor elements 3 are bonded, on the upper surface of the metal circuit pattern 2.

Each of the grooves 4 is formed along the periphery of the semiconductor element 3. Each of the semiconductor elements 3 is individually surrounded by the groove 4 in a plan view.

The grooves 4 prevent the bonding material 5 from flowing to undesired portions in manufacturing the semiconductor device 11. The grooves 4, for example, prevent the bonding material 5 from extending off from the pattern region 2a or 2b, and prevent the pattern regions 2a and 2b from shorting out.

Materials of the insulator 1 are not particularly limited. Examples of the materials of the insulator 1 may include inorganic ceramic materials such as alumina (Al₂O₃), aluminum nitride (AlN), silicon nitride (Si₃N₄), silicon dioxide (SiO₂), and boron nitride (BN), and resins such as silicone resins, acrylic resins, polyphenylene sulfide (PPS), and polybutylene terephthalate (PBT).

Materials of the metal circuit pattern 2 are not particularly limited. Examples of the materials of the metal circuit pattern 2 include copper, copper alloys, aluminum, and aluminum alloys. The surface of the metal circuit pattern 2 may be nickel plated or copper plated.

The bonding material 5 is not particularly limited. The bonding material 5 is, for example, solder or a sintered bonding material. When the semiconductor device 11 is manufactured, the bonding material 5 may be a plate bonding material or a paste bonding material. Here, the bonding material 5 may or need not contain flux.

The semiconductor elements 3 are not particularly limited. The semiconductor elements 3 are, for example, semiconductor elements made of a Si-semiconductor. The semiconductor elements 3 may be semiconductor elements made of a wide bandgap semiconductor with a band gap larger than that of Si, such as a SiC semiconductor, a GaN-based semiconductor, or a diamond semiconductor.

Although FIG. 1 illustrates the four semiconductor elements 3 placed on the metal circuit pattern 2, the number of the semiconductor elements 3 placed on the metal circuit pattern 2 is not limited to four but may be changed as necessary according to the usage.

The sealant 6 is, for example, a resin, for example, silicone gel or an epoxy resin. The sealant 6 is not limited to the silicone gel or the epoxy resin. A resin with a desired coefficient of elasticity and desired heat resistance is available as the sealant 6.

A depth D of the groove 4 (see FIG. 3) is less than the depth of the metal circuit pattern 2. In view of facilitating pouring the sealant 6 into the grooves 4, the depth D is preferably not too larger than the width W of the groove 4, for example, preferably smaller than the width W.

An angle between the undersurface 4c and each side surface of the groove 4 is an obtuse angle. In other words, an angle θ1 between the undersurface 4c and one side surface 4a and an angle θ2 between the undersurface 4c and another side surface 4b are each larger than 90 degrees. The angle θ1 may be identical to or different from the angle θ2. There is no particular limitation on the angles θ1 and θ2 as long as the angles are larger than 90 degrees. Preferably, the angles θ1 and θ2 range from 90 degrees to 150 degrees.

The use of the obtuse angles between the undersurface 4c and the side surface 4a and between the undersurface 4c and the side surface 4b can reduce a contact area of air bubbles created in the grooves 4 with the side surfaces 4a and 4b and the undersurface 4c of each of the grooves 4 due to the surface tension in a process of sealing the semiconductor elements 3 using the sealant 6, more than that when at least one of the angles between the undersurface 4c and the side surface 4a and between the undersurface 4c and the side surface 4b is a right angle or an acute angle. Thus, reduction of the energy required to remove the air bubbles facilitates removal of the air bubbles when the sealant flows. As a result, the air bubbles hardly remain in the grooves 4 after a process of sealing the semiconductor elements 3.

Methods for forming the grooves 4 are not particularly limited. The methods for forming the grooves 4 may include die press forming and cutting, and more preferably, laser illumination. Forming the grooves 4 through the laser illumination improves the productivity and reduces the cost.

More preferably, an angular portion at which the undersurface 4c is connected to the side surface 4a or 4b is rounded.

As described above, in the semiconductor device 11 according to Embodiment 1, the upper surface of the metal circuit pattern 2 includes the grooves 4 in a region sealed by the sealant 6, the region being different from a region to which the at least one semiconductor element 3 is bonded via the bonding material 5, and an angle between each side surface of the groove 4 and the undersurface 4c of the groove 4 is an obtuse angle. Thus, air bubbles hardly remain in the grooves 4 formed in the metal circuit pattern 2 in a process of sealing the semiconductor elements 3. Consequently, the metal circuit pattern 2 hardly peels off from the sealant 6.

### B. Embodiment 2

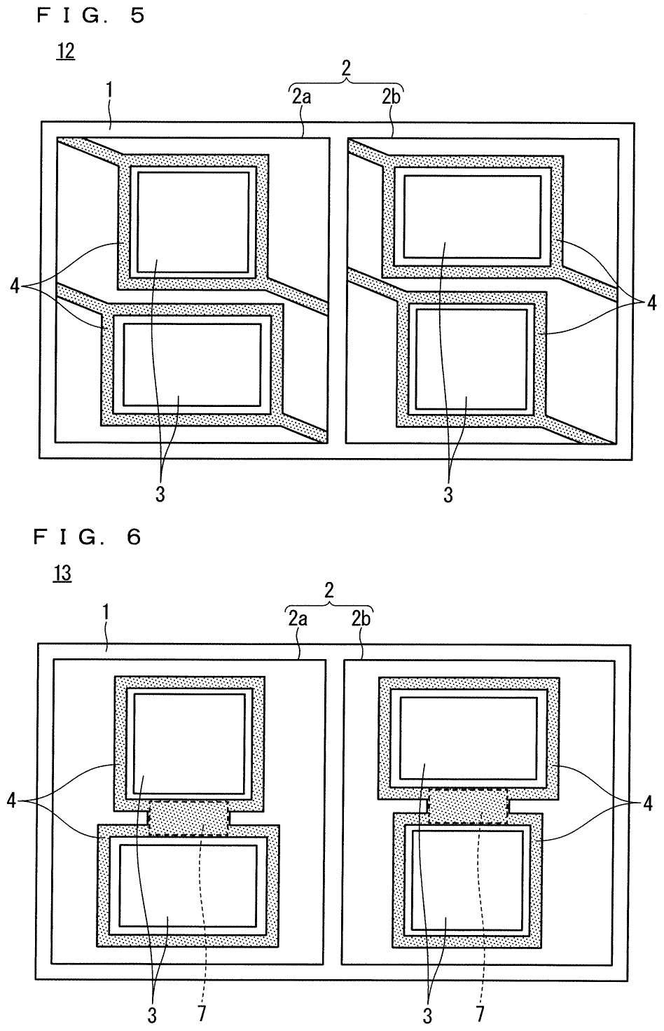

FIG. 4 illustrates an example semiconductor device 12 according to Embodiment 2. FIG. 5 illustrates another example of the semiconductor device 12 according to Embodiment 2. FIGS. 4 and 5 are diagrams corresponding to FIG. 1 according to Embodiment 1.

The semiconductor device 12 differs from the semiconductor device 11 according to Embodiment 1 in the layout of the grooves 4. The semiconductor device 12 is identical to the semiconductor device 11 according to Embodiment 1 in other respects.

In the semiconductor device 12, the grooves 4 extend to peripheral ends of the metal circuit pattern 2 in a plan view as illustrated in FIG. 4. The peripheral ends of the metal circuit pattern 2 in a plan view are peripheral ends of each pattern region (i.e., the pattern regions 2a and 2b) of the metal circuit pattern 2 in a plan view.

Paths of each of the grooves 4 from a portion formed along the periphery of the semiconductor element 3 to the peripheral ends of the metal circuit pattern 2 in a plan view are not particularly limited. As illustrated in FIG. 4 or 5, extension of the grooves 4 from the angular portions around the semiconductor elements 3 to the peripheral ends of the metal circuit pattern 2 in a plan view is preferred, so that the bonding material 5 is prevented from reaching outside the metal circuit pattern 2 through the grooves 4.

Since the grooves 4 include paths of the sealant 6 that is poured over the upper surface of the metal circuit pattern 2 and flows to the end portions of the metal circuit pattern 2, air bubbles hardly ever remain in the grooves 4 and the metal circuit pattern 2 hardly ever peels off from the sealant 6.

### C. Embodiment 3

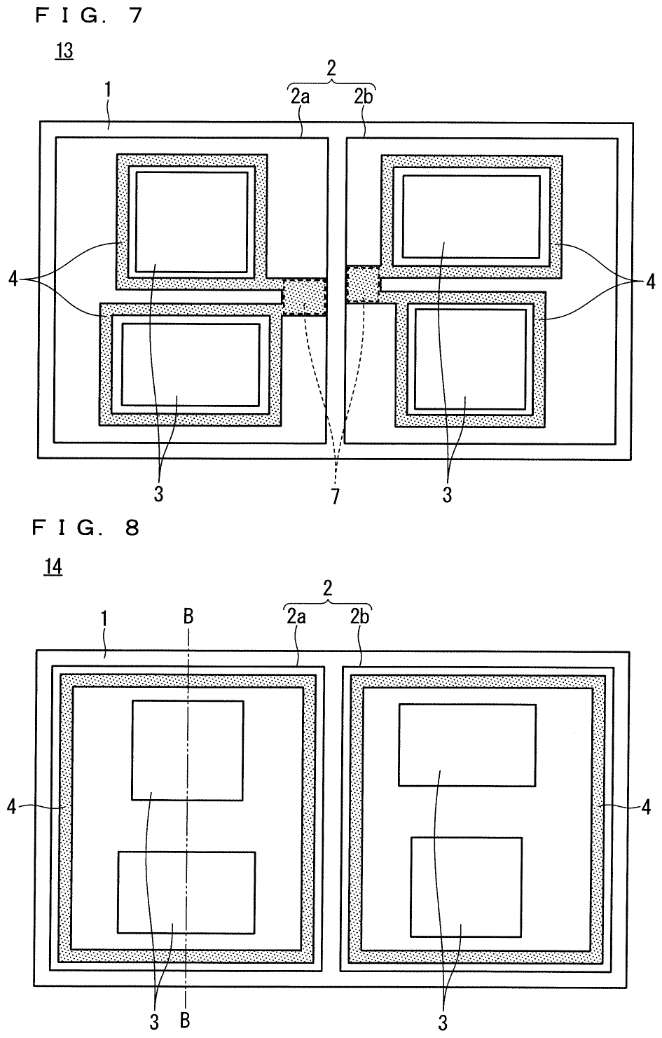

FIG. 6 illustrates an example semiconductor device 13 according to Embodiment 3. FIG. 7 illustrates another example of the semiconductor device 13 according to Embodiment 3. FIGS. 6 and 7 are diagrams corresponding to FIG. 1 according to Embodiment 1.

The semiconductor device 13 according to Embodiment 3 differs from the semiconductor device 11 according to Embodiment 1 in including the grooves 4 with widened portions 7. The widened portions 7 are portions wider than any other portions of the grooves 4. The semiconductor device 13 is identical to the semiconductor device 11 according to Embodiment 1 in other respects.

In a process of manufacturing the semiconductor device 13, for example, the sealant 6 with fluidity is poured into the widened portions 7 in sealing the semiconductor elements 3 with the sealant 6. For example, the sealant 6 poured into the widened portions 7 spreads out into other portions of the upper surface of the metal circuit pattern 2 from the widened portions 7.

Preferentially pouring the sealant 6 into the widened portions 7 in the manufacturing process facilitates upward escape of air bubbles created when the sealant 6 is poured over the upper surface of the metal circuit pattern 2. Thus, the air bubbles hardly remain in the grooves 4. Consequently, the metal circuit pattern 2 hardly peels off from the sealant 6 in the semiconductor device 13.

In the example of FIG. 6, the widened portions 7 are located in the respective center portions of the pattern regions 2a and 2b in a plan view.

In the example of FIG. 7, the widened portions 7 are respective peripheral portions of the pattern regions 2a and 2b in a plan view, and are located in the center of the insulator 1 in the plan view. Although the widened portions 7 extend to the peripheral ends of the metal circuit pattern 2 in a plan view in the example of FIG. 7, portions of the grooves 4 other than the widened portions 7 may extend to the peripheral ends of the metal circuit pattern 2 in the plan view.

An area of the widened portion 7 is not particularly limited as long as the widened portion 7 is wider than any other portions of the grooves 4. Preferably, the area is larger than or equal to 5 mm×5 mm in view of the precision of positioning in pouring the sealant 6 into the widened portions 7.

### D. Embodiment 4

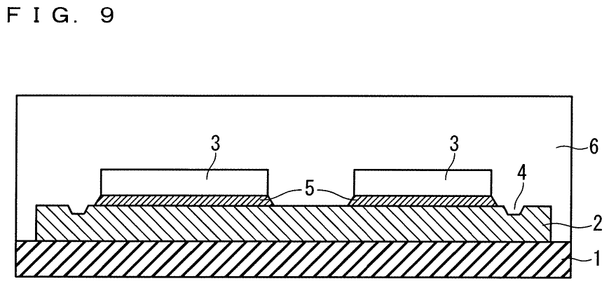

FIG. 8 illustrates a semiconductor device 14 according to Embodiment 4. FIG. 9 is a cross-sectional view of the semiconductor device 14 which is taken along a line B-B in FIG. 8. FIG. 8 is a diagram corresponding to FIG. 1 according to Embodiment 1. FIG. 9 is a diagram corresponding to FIG. 2 according to Embodiment 1.

The semiconductor device 14 according to Embodiment 4 differs from the semiconductor device 11 according to Embodiment 1 in the layout of the grooves 4. The semiconductor device 14 is identical to the semiconductor device 11 according to Embodiment 1 in other respects.

In the semiconductor device 14, the grooves 4 are formed not along the peripheries of the semiconductor elements 3 around the semiconductor elements 3 but along the peripheries of the metal circuit pattern 2. The peripheries of the metal circuit pattern 2 are peripheries of each of the pattern regions (i.e., the pattern regions 2a and 2b) of the metal circuit pattern 2. In other words, the grooves 4 are formed along the respective peripheries of the pattern regions 2a and 2b. Each of the grooves 4 collectively encloses a plurality of the semiconductor elements 3 in a plan view. In other words, the plurality of semiconductor elements 3 are located in one region enclosed by each of the grooves 4. This structure can reduce the space of the semiconductor device 14 more than the structure in which each of the grooves 4 is formed to individually enclose the semiconductor element 3. This structure is effective particularly when a distance between the semiconductor elements 3 is short or when the semiconductor elements 3 are placed in large numbers on one pattern region of the metal circuit pattern 2.

The same layout of the grooves 4, that is, a structure in which the grooves 4 are formed along the peripheries of the metal circuit pattern 2 is applicable to semiconductor devices with different layouts of the semiconductor elements 3 among semiconductor devices each including the metal circuit pattern 2 as the common structure. The structure in which the grooves 4 are formed along the peripheries of the metal circuit pattern 2 is a structure with general versatility. Thus, this structure can reduce the manufacturing cost.

The semiconductor device 14 can be combined with one of or both of the semiconductor device 12 according to Embodiment 2 and the semiconductor device 13 according to Embodiment 3. In other words, the grooves 4 of the semiconductor device 14 may include widened portions, or may extend to the peripheral ends of the metal circuit pattern 2 in a plan view.

Embodiments can be freely combined, and appropriately modified or omitted.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
an insulator;
a metal circuit pattern disposed on the insulator;
at least one semiconductor element bonded to an upper surface of the metal circuit pattern via a bonding material; and
a sealant sealing the at least one semiconductor element,
wherein the upper surface of the metal circuit pattern includes a groove in a region sealed by the sealant, the region being different from a region to which the at least one semiconductor element is bonded via the bonding material, and
an angle between each side surface of the groove and an undersurface of the groove is an obtuse angle.

2. The semiconductor device according to claim 1,
wherein the groove extends to a peripheral end of the metal circuit pattern in a plan view.

3. The semiconductor device according to claim 1,
wherein the number of the at least one semiconductor element is two or more, and
the groove collectively encloses some of the at least one semiconductor element in a plan view.

4. The semiconductor device according to claim 1,
wherein the groove is formed along a periphery of the metal circuit pattern.

5. The semiconductor device according to claim 1,
wherein the groove individually encloses the at least one semiconductor element in a plan view.

6. The semiconductor device according to claim 1,
wherein the groove includes a widened portion wider than any other portions of the groove.

7. A method for manufacturing the semiconductor device according to claim 6, comprising
pouring the sealant with fluidity into the widened portion in sealing the at least one semiconductor element with the sealant.
